(19) United States
(12) Patent Application Publication
(10) Pub. No.: US 2025/0383397 A1
(43) Pub. Date: Dec. 18, 2025

(54) TESTING DEVICE FOR TESTING SEMICONDUCTORS AND METHODS OF FABRICATION

(71) Applicant: INTERNATIONAL BUSINESS MACHINES CORPORATION, ARMONK, NY (US)

(72) Inventors: John Knickerbocker, Monroe, NY (US); Pablo Nieves, Pinebluff, NC (US); Ishtiaq Ahsan, Halfmoon, NY (US); Mark Christopher Johnson, South Burlington, VT (US)

(21) Appl. No.: 18/745,997

(22) Filed: Jun. 17, 2024

(51) Int. Cl. G01R 31/28; G01R 3/00

(52) U.S. Cl. CPC G01R 31/2867; G01R 3/00; G01R 31/2875; G01R 31/2877

(57) ABSTRACT

A testing device includes N devices, and N−1 probe heads. N is an integer. An M-th probe head includes devices 1 to N-M electrically connected to each other. The M-th probe head is configured to test the M-th device, and M is an integer between 1 and N−1.

### BACKGROUND

### Technical Field

The present disclosure generally relates to semiconductors, and more particularly, to testing semiconductor device structures, and methods of creation thereof.

### Description of Related Art

Semiconductor testing ensures the reliability, functionality, and quality of semiconductor devices, which are integral components in modern electronics. This testing process helps identify defects and failures in semiconductor chips before they are integrated into consumer electronics, automotive systems, and other applications. By detecting errors early, semiconductor testing reduces the risk of costly recalls and enhances product safety. Additionally, it supports the development of advanced technologies by allowing manufacturers to verify compliance with industry standards and improve product performance through iterative design refinements.

### SUMMARY

According to an embodiment, a semiconductor testing device includes N devices and N−1 probe heads. N is an integer and an M-th probe head includes device 1 to device N−M electrically connected to each other. The M-th probe head is configured to test the M-th device, and M is an integer between 1 and N−1.

In one embodiment, the N devices are chiplets or dice.

In one embodiment, the N devices are coupled to each other.

In one embodiment, the semiconductor testing device includes at least one of the N devices is a semiconductor wafer, and the semiconductor wafer is one of: a functional wafer, a full thickness wafer, or a thinned wafer.

In one embodiment, the handler wafer is one of: a silicon handler wafer, or a thermally conductive handler wafer.

In one embodiment, the handler wafer includes integrated cooling channels configured to spread and remove heat from the semiconductor wafer.

In one embodiment, the handler wafer includes through-silicon via (TSV) configured to spread and remove heat from the semiconductor wafer.

In one embodiment, the semiconductor testing device is configured to test the N devices within a temperature range from −55° C. to 150° C.

In one embodiment, the semiconductor testing device is configured to power up at least one of the devices via the probe heads.

According to an embodiment, a method for fabrication of a semiconductor testing device includes forming N devices under test coupled to each other, forming N−1 probe heads, and testing M-th device by the M-th probe head. N is an integer, an M-th probe head is formed by electrically connecting device 1 to device N-M to each other, and M is an integer between 1 and N−1.

In one embodiment, the method includes, upon testing the M-th device by the M-th probe head, forming an M+1 probe head by electrically connecting device 1 to device N-M+1, and testing M+1-th device by the M+1 probe head.

In one embodiment, at least one of the devices is a semiconductor wafer, and the semiconductor wafer is one of: a functional wafer, a full thickness wafer, or a thinned wafer.

In one embodiment, the method includes connecting the semiconductor wafer to a handler wafer, and spreading and removing heat from the semiconductor wafer by the semiconductor testing device via the handler wafer.

In one embodiment, the method includes forming integrated cooling channels within the handler wafer and spreading and removing heat from the semiconductor wafer via the integrated cooling channels.

In one embodiment, the method includes forming through-silicon via (TSV), and spreading and removing heat from the semiconductor wafer via the TSV.

In one embodiment, the method includes powering up at least one of the devices by the probe heads.

According to an embodiment, a semiconductor testing device includes a test head including one or more electrical connections, one or more testing probes, and a device under test, and a handler wafer connected to the device under test. The semiconductor testing device is configured to power up the device under test during testing.

In one embodiment, the test head includes heating and cooling channels, and the test head is configured to heat up and cool down the test head from −55° C. to 150° C.

In one embodiment, the device under test is one of: a functional wafer, a full thickness wafer, or a thinned wafer.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1 illustrates a semiconductor testing device, in accordance with some embodiments.

FIGS. 2A-2C illustrate various components of a semiconductor testing device, consistent with an illustrative embodiment.

FIG. 3 illustrates a block diagram of a method for forming the semiconductor testing device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

Asused herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

According to an embodiment, a semiconductor testing device N devices an N−1 probe heads. N is an integer and an M-th probe head includes device 1 to device N-M electrically connected to each other. The M-th probe head is configured to test the M-th device, and M is an integer between 1 and N−1. Thus, the semiconductor testing device is capable of adjusting to test various devices in a single chip.

In some embodiments, the devices are chiplets or die. Various types of semiconductor devices can be tested.

In some embodiments, the devices are coupled to each other. The semiconductor testing device is suitable for highly dense coupled chips.

In some embodiments, the semiconductor testing device includes at least one of the devices is a semiconductor wafer, and the semiconductor wafer is one of: a functional wafer, a full thickness wafer, or a thinned wafer. Thus, the semiconductor testing device is capable of testing devices with various sizes.

In some embodiments, the handler wafer is one of: a silicon handler wafer, or a thermally conductive handler wafer. The handler wafer can play role in thermal management.

In some embodiments, the handler wafer includes integrated cooling channels configured to spread and remove heat from the semiconductor wafer. Thus, the handler wafer can actively play a role in the thermal management.

In some embodiments, the handler wafer includes through-silicon via (TSV) configured to spread and remove heat from the semiconductor wafer. The handler wafer can use vertical through holes to heat or cool the device under test.

In some embodiments, the semiconductor testing device is configured to test the devices within a temperature range from −55° C. to 150° C. Thus, the semiconductor testing device can test the devices within a wide range of temperature.

In some embodiments, the semiconductor testing device is configured to power up at least one of the devices via the probe heads. Thus, any one of the devices can be powered up without needing to power up other devices.

According to an embodiment, a method for fabrication of a semiconductor testing device includes forming N devices coupled to each other, forming N-1 probe heads, and testing M-th device by the M-th probe head. N is an integer, an M-th probe head is formed by electrically connecting device 1 to device N-M to each other, and M is an integer between 1 and N−1. Thus, the semiconductor testing device is capable of adjusting to test various devices in a single chip.

In some embodiments, the method includes, upon testing the M-th device by the M-th probe head, forming an M+1 probe head by electrically connecting device 1 to device N-M+1, and testing M+1-th device by the M+1 probe head. Thus, after each test, the semiconductor testing device is adjusted to test another device continuously.

In some embodiments, at least one of the devices is a semiconductor wafer, and the semiconductor wafer is one of: a functional wafer, a full thickness wafer, or a thinned wafer. Thus, the semiconductor testing device is capable of testing devices with various sizes.

In some embodiments, the method includes connecting the semiconductor wafer to a handler wafer, and spreading and removing heat from the semiconductor wafer by the semiconductor testing device via the handler wafer. The handler wafer can use vertical through holes to heat or cool the device under test.

In some embodiments, the method includes forming integrated cooling channels within the handler wafer and spreading and removing heat from the semiconductor wafer via the integrated cooling channels. The handler wafer can play an active role in thermal management.

In some embodiments, the method includes forming through-silicon via (TSV), and spreading and removing heat from the semiconductor wafer via the TSV. The handler wafer can use vertical through holes to heat or cool the device under test.

In some embodiments, the method includes powering up at least one of the devices by the probe heads. Thus, any one of the devices can be powered up without needing to power up other devices.

According to an embodiment, a semiconductor testing device includes a test head including one or more electrical connections, one or more testing probes, and a device under test, and a handler wafer connected to the device under test. The semiconductor testing device is configured to power up the device under test during testing. Thus, the semiconductor testing device is capable of adjusting to test various devices in a single chip.

In some embodiments, the test head includes heating and cooling channels, and the test head is configured to heat up and cool down the test head from −55° C. to 150° C. Thus, the semiconductor testing device can test the devices at a wide range of temperatures.

In some embodiments, the device under test is one of: a functional wafer, a full thickness wafer, or a thinned wafer. Thus, a wide range and size wafers can be tested.

The concepts herein relate to thermal testing of the semiconductor devices, which is a component used in the semiconductor testing process, specifically designed to assess how semiconductor devices perform under varying temperature conditions. The term “known good die” (KGD) refers to individual semiconductor chips (or dies) that have been tested and verified to meet the required operational specifications before being used in further applications, such as multi-chip modules or integrated into systems-on-chip. These chips are typically tested at the wafer-level using specialized test equipment that can ensure their functionality and performance. The importance of KGD arises from the consideration to minimize the risk and cost associated with using defective chips in complex and often expensive electronic assemblies. By using KGD manufacturers can significantly enhance the reliability of the final products and avoid the costs associated with reworking or scrapping faulty assemblies.

However, testing semiconductor chips presents a myriad of challenges that significantly impact the yield, performance, and reliability of electronic devices. These challenges stem from several technical and engineering aspects throughout the design, manufacturing, and testing phases. Issues such as coplanarity, where surfaces are not perfectly flat, can lead to poor contacts during bonding, resulting in defective assemblies. Moreover, the increasing density of input/output connections with finer pitches compounds these challenges, necessitating highly precise alignment to avoid connectivity issues. Die shift, another common issue, occurs when the die moves from its intended position during packaging, potentially disrupting connections and leading to functional failures.

Thermal management is another critical area, particularly as devices become more powerful and compact, generating more heat. Effective thermal solutions are essential to maintain performance and extend the lifespan of devices. Additionally, the mismatch in the coefficient of thermal expansion (CTE) among different materials in the semiconductor package can lead to mechanical stresses, affecting the device's reliability and longevity. As semiconductor technology advances, testing KGD and ensuring package integrity are increasingly vital to avoid costly reworks and product failures. Furthermore, the integration of advanced technologies like high-bandwidth memory (HBM) and die stacking at fine pitches on silicon interposers introduces complexities in volt and power delivery, requiring sophisticated distribution systems to maintain functionality. Maintaining low costs while adopting fine pitch I/O and hybrid bonding technologies is crucial for competitive scaling in semiconductor manufacturing. These advancements push the boundaries of interconnect density and performance but require innovative solutions to ensure reliability and yield in final products.

In view of the above considerations, disclosed is a semiconductor testing device to ensure the durability and reliability of semiconductor devices, thus, to contribute to the overall quality assurance in the production of electronic devices. The disclosed semiconductor testing device introduces a comprehensive suite of capabilities designed to address the complexities of modern semiconductor testing and assembly and supports device testing with silicon and/or high thermal conductivity heat spreaders, while reducing thermal resistance. This feature is particularly useful for wafer-level testing (WLT), die-under-test (DUT), chiplet testing, and module testing, enhancing the effectiveness of thermal heat spreaders and cooling solutions used during these processes.

The semiconductor testing device is equipped with a test head and features fine pitch, low force test probes with improved precision, suitable for testing densely packed semiconductor designs. The probe heads facilitate passive and active tests, evaluating performance metrics such as frequency and leakage and incorporating AI/data trending capabilities for ensuring the quality of KGD, known good partial dies, and integrated redundancies. Moreover, the semiconductor testing device supports wafer-level die sorting and provides a platform for advanced testing of chiplets, advanced packaging, and known good sub-assemblies. The semiconductor testing device includes options for rework, enhanced thermal testing, precise power delivery, built-in self-test (BIST), and integrated testing functionality. Additionally, the semiconductor testing device accommodates advanced solder interconnection and testing, as well as copper/hybrid bonding and testing technologies, which are crucial for the development of robust semiconductor packages.

The semiconductor testing device further supports advanced packaging configurations, such as silicon interposer to organic, silicon interposer to thin film (TF) to organic packages, and advanced TF or TF interposer to organic packages. Furthermore, the semiconductor testing facilitates the integration and testing of advanced AI modules, underscoring its adaptability to future technological advancements and its role in pushing the boundaries of semiconductor testing technology.

Accordingly, the teachings herein provide methods and systems of a testing device to test semiconductor devices. The techniques described herein may be implemented in a number of ways. Example implementations are provided below with reference to the following figures.

### Example Semiconductor Testing Device Structure

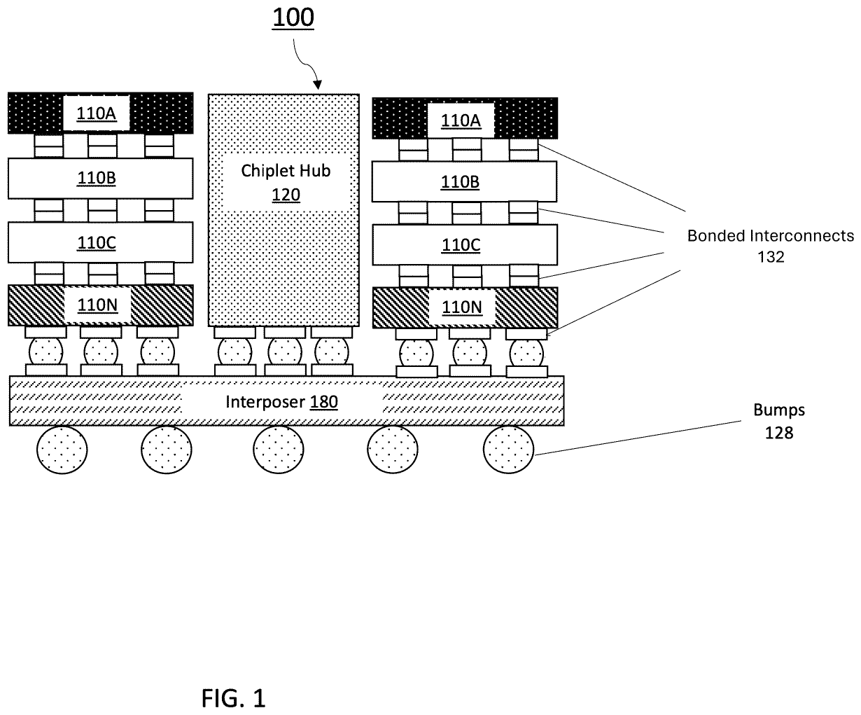

Reference now is made to FIG. 1, which is a simplified cross-sections view of a semiconductor testing device, consistent with an illustrative embodiment. FIG. 1 is representative of a 3D semiconductor package consisting of multiple bonded chiplets, interposers, and bonded interconnects of various types. The packaged semiconductor device 100 can include multiple chiplets that need to be tested individually before being packaged. However, when tested individually, the chiplets can lose functionality that is only available when the other chiplets are connected to it.

In various embodiments, the package semiconductor device 100 includes N devices 110A, 110B, 110C, . . . , 110N, N being an integer, and N−1 probe heads. The devices 110A, 110B, 110C, . . . , 110N can include a memory such as a chiplet SRAM, a coupled chiplet, an Al cores, a chiplet hub, a heating/cooling unit, a handler wafer, and a fixture for mechanical support. The package semiconductor device 100 can be used to test one or more of the devices 110A, 110B, 110C, . . . , 110N. In various embodiments, the device under test, i.e., the devices 110A, 110B, 110C, . . . , 110N, can include chiplets or dies, such as die under test (DUT), chiplet under test (CUT), wafer under test (WUT), stacked DUT, stacked CUT, module under test (MUT), and sub-assembly under test (SAUT). One or more of the devices 110A, 110B, . . . , 110N can be coupled to each other. For example, the one or more devices 110A, 110B, 110C . . . , 110N can be stacked over each other to form a vertical stack of devices, or next to each other.

In some embodiments, the package semiconductor device 100 can include an interposer 180. The interposer 180 can act as an intermediary layer that facilitates the connection between the probe heads 132 and the device under test to improve performance, reduce power consumption, and save space. The interposer 180 can be made of materials such as silicon, glass, or organic substrates, and can contain a network of electrical connectors or TSVs. The electrical connectors and TSVs can allow for the vertical and horizontal routing of signals and power between different layers of the package semiconductor device 100. In addition to improving electrical connectivity, the interposer 180 can enhance the thermal and mechanical performance of the package semiconductor device 100 and help distribute and manage the heat generated by different components and testing processes, thus aiding in the overall thermal management of the package semiconductor device 100. In some embodiments, the interposer 180 can provide mechanical support, helping to alleviate stress caused by thermal expansion and contraction among different materials in the package semiconductor device 100 to maintain the integrity and longevity of the components.

In some embodiments, the package semiconductor device 100 is configured to function in a way that an M-th probe head includes device 1 to device N-M which are electrically connected to each other. M is an integer between 1 and N-M. In such embodiments, the M-th probe head is configured to test the M-th device. In some embodiments, once the M-th device is tested by the M-th probe head. The M+1 probe head is formed by electrically connecting devices number 1 to N-M+1 number. Subsequently, the M+1-th device is tested by the M+1 probe head.

In some embodiments, the devices 110A, 110B, . . . , 110N can include a memory, such as a chiplet static random-access memory (SRAM), which is a self-contained memory module that can be integrated with other chiplets to construct a comprehensive system within a single package. The SRAM chiplet can provide fast access memory, typically utilized as cache memory in processors. Each SRAM chiplet can include all necessary components to operate independently, comprising memory arrays, control logic, and interfaces for communication with other chiplets.

In some embodiments, the devices 110A, 110B, . . . , 110N can include a chiplet hub 120. The chiplet hub 120 can serve as a central point for communication and coordination among multiple chiplets within the package semiconductor device 100 and facilitate data transfer and manage interactions among these chiplets. In an embodiment, the chiplet hub 120 can include interfaces and interconnects that handle the routing of signals, power, and data between chiplets. For instance, the chiplet hub 120 can manage the input/output operations, distribute power to other chiplets, and control data bandwidth and latency. The chiplet hub 120 can further allow for a scalable and flexible architecture, where additional functionalities can be added simply by integrating more chiplets around the hub. This scalability is particularly beneficial in applications requiring customization or regular updates, such as data centers, networking equipment, and consumer electronics. Additionally, by centralizing communication functions, the chiplet hub 120 can reduce the complexity and power consumption of each individual chiplet, leading to overall improvements in energy efficiency and performance.

In some embodiments, the devices 110A, 110B, . . . , 110N can include a universal chiplet interconnect express (UCIe). The UCle can facilitate high-bandwidth connections between chiplets to ensure that data can be transferred quickly and with minimal latency between the chiplets. The UCle can improve the energy efficiency by minimizing power leakage and reducing the energy required per bit of data transferred, thus reducing operational costs and thermal outputs. In some embodiments, the UCle can enable the integration of various chiplets with different functionalities—such as CPUs, GPUs, memory, and I/O components—into a single chiplet using a consistent interconnect fabric.

In various embodiments, each probe head can be configured to facilitate targeted testing of individual chiplets within a stack, thereby allowing for identification of defective chiplets. This method can reduce unnecessary waste by ensuring that only the defective chiplets are identified and removed from the production line, while non-defective ones are retained for use. As a result, the package semiconductor device 100 is poised to enhance yield rates, reduce costs, and improve the reliability of semiconductor devices in various applications. The packaged semiconductor device 100 can include a variety of electrical connectors, such as bumps and pads 132 to establish electrical connections between different components of the package semiconductor device 100, the devices 110A, 110B, . . . , 110N and the device under test. And also, a variety of chip contacts such as bumps and pads to contact the packaged device 128. In some embodiments, a chiplet integration can manage the chiplets within the stack of chiplets.

In some embodiments, at least one of the devices is a semiconductor wafer. The semiconductor wafer can be a functional wafer, a full thickness wafer, or a thinned wafer. The functional wafer can be a silicon wafer that has undergone the complete semiconductor fabrication process and contains active or functional electronic circuits. In other words, the functional wafer is a finished product at the wafer-level, meaning all the photolithography, doping, etching, and other processing steps have been completed, and the wafer contains multiple dies that are ready to be tested. Functional wafers can be tested for functionality before they are diced into individual chips or dies, ensuring that each die works as intended. The full thickness wafer can retain its original thickness throughout the fabrication process. In some embodiments, the full thickness wafer has thicknesses ranging from about 0.5 mm to over 1 mm, depending on the wafer diameter and the specific requirements of the semiconductor devices being fabricated. Full thickness wafers provide structural robustness and are less susceptible to handling damage during the processing stages. The thinned wafer, on the other hand, has been mechanically or chemically thinned down after the circuit fabrication is complete. Thinning a wafer can improve thermal management, reduce form factors, and enhance the electrical performance of the semiconductor devices, especially in applications requiring high-density packaging such as stacked chips or 3D ICs.

Since thinned wafers can be more fragile and require careful handling, in some embodiments, the semiconductor wafer can be connected to a handler wafer during the testing. The handler wafer can be a silicon handler wafer or a thermally conductive handler wafer.

The package semiconductor device 100 can actively manage the temperature of the probe heads, swiftly eliminating any moisture that has formed. By precisely controlling the temperature at the point of contact, an integrated heating/cooling unit not only reduces the waiting time significantly but also enhances the accuracy and reliability of the testing process. Thus, in some embodiments, the handler wafer can include integrated heating/cooling channels to spread and remove heat from the semiconductor wafer. The heating/cooling channels can be part of a heating/cooling unit which can include an air heating/cooling unit, a liquid heating/cooling unit, or a two-phase heating/cooling unit. The heating/cooling unit can spread and remove heat within the device under test or any other devices within the package semiconductor device 100.

In some embodiments, the handler wafer can include through-silicon via (TSV) to spread and remove heat from the semiconductor wafer. The TSV can be a vertical electrical connection that penetrates completely through a wafer or die, providing a conductive path between different layers of the semiconductor stack, which can facilitate creating high-density, high-performance integrated circuits (ICs) by stacking multiple chips and establishing vertical connections, as opposed to traditional horizontal interconnects on a single plane. In some embodiments, the TSV can increase performance by reducing the distance electrical signals need to travel, thus lowering latency and enhancing connection speed within ICs. In some embodiments, the TSV can aid in thermal management by serving as heat spreaders that help dissipate heat away from hot spots of the package semiconductor device 100 or the device under test, improving the accuracy of the testing processes.

In some embodiments, the package semiconductor device 100 can spread and remove heat from the semiconductor wafer via the handler wafer. The handler wafer can utilize the TSV and/or the heating/cooling unit to spread and remove heat from the semiconductor wafer. The package semiconductor device 100 can test the devices within a temperature range from about −550° C. to about 150° C. Thus, the package semiconductor device 100 is capable of testing temperatures up to 150 C, which is an industry recognized high limit for operation of a junction (for electron mobility).

The package semiconductor device 100 can power up at least one of the devices 110A, 110B, 110C, . . . , 110N via the probe heads. The probe heads can establish electrical connections between various components of the package semiconductor device 100 and the device under test, and be used to power up the various components of the package semiconductor device 100 and the device under test. In some embodiments, the probe heads can assess how the device under test will perform thermally in real-world applications, which can affect its reliability, efficiency, and lifespan. In some embodiments, the probe heads can integrate a mechanism for heating and cooling the device under test directly to allow the device under test to be subjected to a range of temperatures, simulating different operating environments. The integrated mechanism for heating and cooling the device under test can be part of the heating/cooling unit or be a separate mechanism. The probe heads can make direct contact with the device under test by using thermally conductive materials such as copper or silver, to ensure effective heat transfer. During the testing process, the probe heads not only can apply the required temperatures to the device under test but also can measure the response of the semiconductor material. This includes changes in electrical characteristics due to temperature variations, which can indicate potential performance issues or failures.

The package semiconductor device 100 can offer pitch sizes ranging from about 150 micrometers down to about 0.5 micrometer to align with the increasing density of connections on modern semiconductor devices. In some embodiments, this reduction in pitch size allows for more probe heads to be packed into a smaller area, facilitating the testing of more complex and higher performance devices that require numerous connections for full functionality verification. As such, the package semiconductor device 100 can test a 3D stacked devices, a 2.xD stacked devices, and a 2D stacked devices. The probe heads can further provide electrical connections between the package semiconductor device 100 and the device under test.

In some embodiments, the fixture can support the handler wafer. The fixture can be a thermally enabled fixture or base, which includes a mechanical stiffener and load support. In some embodiments, the fixture can provide mechanical support to the handler wafer, in case of thinned wafer, and the device under test, ensuring structural integrity during various testing processes where physical and thermal stress can compromise the delicate components. In some embodiments, the fixture can stabilize the device under test during testing, preventing warping or damage under load. The mechanical stiffener in the fixture can distribute weight and pressure evenly across the device's surface, which facilitates testing involving physical contact or pressure, such as during probing. In some embodiments, the fixture can be thermally enabled to effectively manage the temperature of the handler wafer and the device under test. In an embodiment, the fixture can include parts of the integrated heating/cooling unit that maintain specific temperature conditions required for accurate test results. The combination of mechanical support and thermal management can ensure that the fixture holds the device under test securely and contributes to the reliability and accuracy of the testing process by maintaining optimal mechanical and thermal conditions.

In some embodiments, the fixture is crafted primarily from silicon due to its favorable mechanical and thermal properties. In an embodiment, the fixture is integrated with the heating/cooling unit, through which a specialized fluid circulates through the channels within the fixture. This circulation maintains temperature control, allowing for rapid and uniform removal or supply of heat to the device under test during testing phases. The fixture can be structured to support loads during testing and prevent physical deformation or displacement that could influence test outcomes. The fixture material can be selected for its high thermal conductivity, which aids in the effective dissipation of heat during the testing process.

In some embodiments, the package semiconductor device 100 can include thermal sensors. In addition to the thermal sensors, the package semiconductor device 100 can include load sensors, and/or stress sensors. The thermal sensors, load sensors, and stress sensors can be part of one of the components of the package semiconductor device 100, e.g., part of the probe heads, or be separate sensors connected to the package semiconductor device 100.

In various embodiments, the thermal sensors, load sensors, and stress sensors can provide data to ensure the reliability and functionality of the devices under test at various conditions. The thermal sensors can monitor the temperature of the device under test by accurately measuring temperature changes induced during the testing processes. Load sensors can be used to measure the mechanical forces applied to the device under test during testing. Stress sensors can detect and measure the strain and stress experienced by the device under test during testing and provide information on how the device under test responds to physical stresses, such as those caused by thermal expansion, mechanical loads, or packaging processes. In some embodiments, the package semiconductor device 100 includes test contacts. The test contacts can be integrated with the device under test, or with the load sensors or the stress sensors.

In some embodiments, the package semiconductor device 100 can include an artificial intelligence unit, an AI unit. The AI unit can be part of the chiplet hub or any other chiplets in the package semiconductor device 100 or a separate chiplet. The AI unit can utilize test data gathered from the device under test to determine the number of probe heads needed to be used for testing the device under test. This way, only the required number of probe heads are used for the device under test, which can speed up the testing processes and reduce the energy consumption by the package semiconductor device 100. Additionally, the AI unit can utilize previous test data of various devices under test and then determine the characteristics of a new device under test.

In some embodiments, temperature sensors are incorporated within the probe heads, or within the device under test, which can provide real-time feedback during testing. These temperature sensors dynamically control the temperature throughout the test process, ensuring the device under test, whether it be a single die, die stack, wafer, module, or sub-assembly, is maintained within optimal thermal conditions to accurately simulate real-world operational environments.

In various embodiments, the package semiconductor device 100 incorporates the probe heads, which are capable of making low-force contacts while still managing to power up the device under test or other components of the package semiconductor device 100. The probe head can be constructed of one or more of the chiplets in the packaged semiconductor device 100 utilized to build a test probe head. For example, if the user wants to test chiplet 110N in FIG. 1, to get full functionality, the chiplet 110B, and/or 110A, can be coupled to the chiplet 110N. Thus, a new test probe head that contains chiplet 110A and chiplet 110B can be created, which can be coupled to the chiplet 110N via test probes.

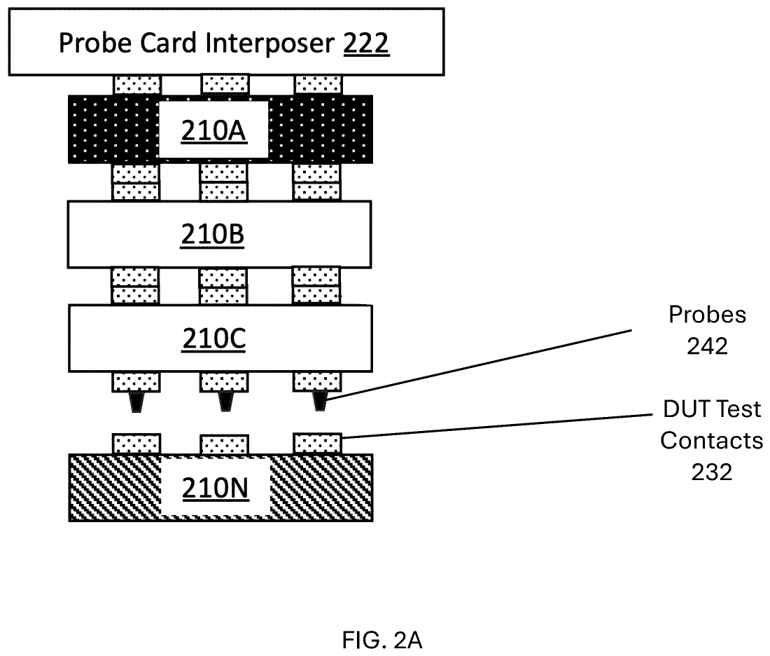

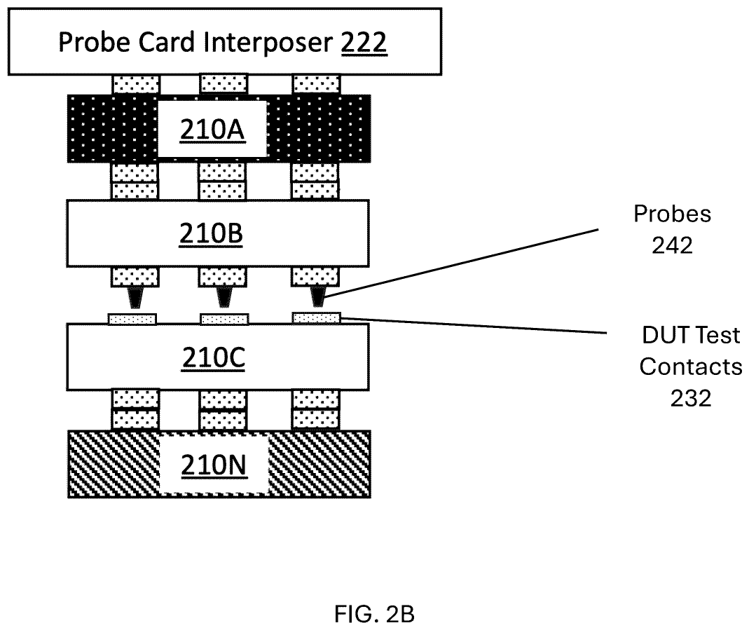

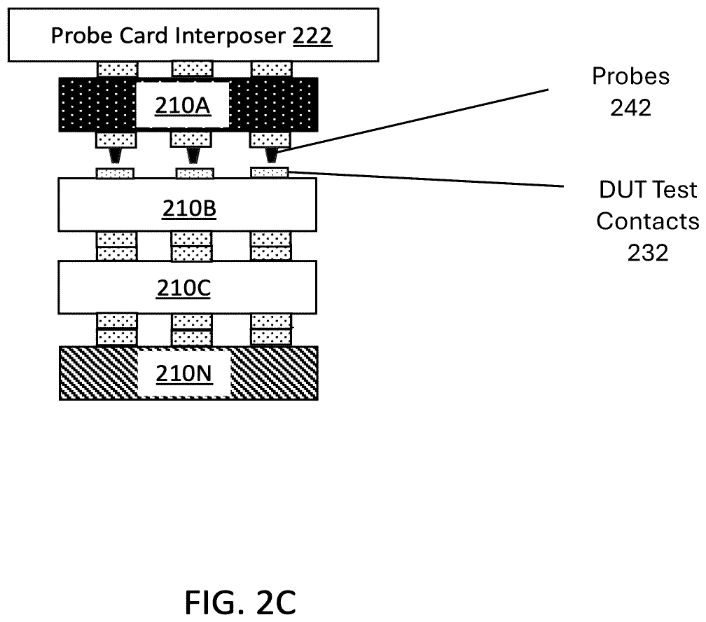

This represents a significant improvement over traditional testing devices, which may not be able to fully power up the full functionality of a chiplet while being tested individually. In contrast, the embodiments described in FIGS. 2A-2C create capability for testing the chiplets functionality more completely and with greater precision for characterizing the chiplet.

FIGS. 2A-2C illustrate various components of a semiconductor testing device, according to some embodiments. In some embodiments, the semiconductor testing device can include a probe card interposer 222, one or more chiplets, 210A, 210B, 210C, . . . , 210N, and probes 242. The custom probe card is built using chiplets from the final product package. N−1 chiplets may be bonded together 132 and to the probe card interposer 222 to produce the custom probe device. Probe structures 242, such as MEMs pins, uPillars, or other advanced probes, that are suitable to probe the test contacts 232 of the chiplet being tested are added to the custom probe head. The probe card interposer 222 can be made of materials such as silicon, glass, or organic substrates, and can contain a network of electrical connectors or TSVs. The electrical connectors and TSVs can allow for the vertical and horizontal routing of signals and power between different layers of the package semiconductor device. In addition to improving electrical connectivity, the probe card interposer 222 can enhance the thermal and mechanical performance of the package semiconductor device and help distribute and manage the heat generated by different components and testing processes, thus aiding in the overall thermal management of the package semiconductor device. In some embodiments, the probe card interposer 222 can provide mechanical support, helping to alleviate stress caused by thermal expansion and contraction among different materials in the package semiconductor device to maintain the integrity and longevity of the components.

As a non-limiting example, in case of a semiconductor device composed of multiple chiplets, such as a stack with four distinct chiplets, in a conventional testing, once one or more of the chiplets of the chiplet stack fails the test, all components of the stack are discarded, which is inefficient and wasteful, particularly when only one of the chiplets is defective. The package semiconductor device can include four separate probe heads (N=4), each designed to test individual chiplets within the stack without the need to discard non-defective chiplets. Each probe head can be configured to test specific chiplets within the four-chiplet stack. The configuration can be as follows:
Probe Head 1: This probe head is designed to test chiplet 1 while chiplets 2, 3, and 4 are electrically connected but not under test. This setup can allow for the isolation and testing of chiplet 1's functionality independently from the others, determining its efficacy or defects.
Probe Head 2: Equipped to test the combined functionality of chiplet 1 and chiplet 2, this probe head connects chiplets 3 and 4, but they are not actively tested. This can allow for the evaluation of chiplet 2's performance in the context of its integration with Chiplet 1, identifying any defects while preserving the integrity of the other chiplets.
Probe Head 3: This probe head tests the trio of chiplet 1, chiplet 2, and chiplet 3, with only chiplet 4 being passive. It can assess the collective functionality and interaction of the first three chiplets, pinpointing defects in chiplet 3 without compromising the non-defective chiplets.
Probe Head 4: Designed to test all four chiplets together, this probe head can verify the entire stack's integration and functionality, confirming the operational status of chiplet 4 within the fully assembled stack.

The accelerator can enhance the testing process, either by speeding up the test or by improving the accuracy and repeatability of the results. The accelerator can improve the efficiency of heating and cooling elements within the package semiconductor device, allowing for rapid temperature changes and quick stabilization of the device under test, which is particularly salient for assessing reliability and performance under thermal stress, where the device under test undergoes multiple rapid thermal cycles.

Additionally, in some embodiments, the accelerator can involve hardware or software enhancements that speed up data acquisition, processing, and analysis. Furthermore, the accelerator can automate various aspects of the testing process, such as ensuring precise contact between pads 232 and the device under test or automating test sequences based on real-time data feedback to enhance test efficiency and reduce the potential for human error. The memory can store the test results and test conditions.

The integration of interposers, accelerator and the memory can enable transitioning from coarser pitches to very fine pitches, incorporating built-in test circuits within the structure. Consequently, such an integration allows for selective testing of individual components, such as testing only the accelerator within a multi-component assembly.

The semiconductor testing device can leverage wafer-level testing, where other components, e.g., the accelerator, can be tested across the entire wafer, or a specific substrate can be targeted for testing, focusing only on desired components. This method ensures that only components meeting the stringent quality standards are progressed to the next stages of manufacturing, thereby facilitating the assembly of known good dies. The probe heads 232 are designed to minimize contamination and withstand extensive use, capable of testing thousands, even hundreds of thousands, of dies before requiring replacement. This durability can facilitate maintaining high testing throughput and reliability, ensuring the cleanliness of both the pads 232 and the wafers throughout the testing process.

In some embodiments, the semiconductor testing device can accommodate and test device under test with variable heights, with the capability of positioning arrays of pads 232 at various pitches. Such a flexibility can maintain contact with the device under test across the probe card interposer 222, and/or the accelerator, and/or the memory. FIG. 2A illustrates a semiconductor testing device with the chiplet 210N as the device under test, and chiplets 210A, 210B and 210C as parts of the probe head. FIG. 2B illustrates a semiconductor testing device with the chiplets 210C and 210N as device under test and chiplets 210A and 210B as parts of the probe head. FIG. 2C illustrates a semiconductor testing device with the chiplets 210B, 210C, and 210N as device under test and the chiplet 210A as part of the probe head.

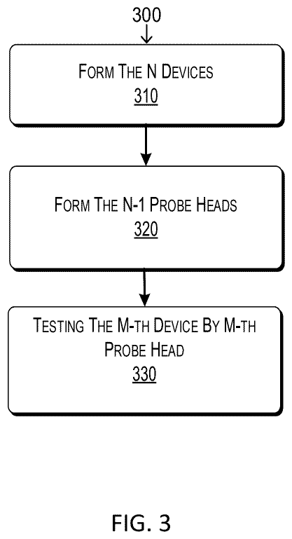

FIG. 3 illustrates a block diagram of a method 300 for forming the semiconductor testing device, in accordance with some embodiments. As shown by block 310, N devices are formed stacked over each other.

As shown by block 320, N−1 probe heads are formed.

As shown by block 330, the M-th device by the M-th probe head is tested. An M-th probe head is formed by electrically connecting device 1 to device N-M to each other, N and M are integers, and M is between 1 and N−1.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### Conclusion

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor testing device, comprising:
N devices, wherein N is an integer; and
N−1 probe heads, wherein:
an M-th probe head, of the N−1 probe heads, includes devices 1 to N-M of the N devices, which are electrically connected to each other;
the M-th probe head is configured to test an M-th device of the N devices; and
M is an integer between 1 and N−1.

2. The semiconductor testing device of claim 1, wherein the N devices are chiplets or die.

3. The semiconductor testing device of claim 1, wherein the N devices are coupled to each other.

4. The semiconductor testing device of claim 1, wherein:
at least one of the devices is a semiconductor wafer; and
the semiconductor wafer is one of: a functional wafer, a full thickness wafer, or a thinned wafer.

5. The semiconductor testing device of claim 4, wherein:
the semiconductor wafer is coupled to a handler wafer; and
the semiconductor testing device is further configured to spread and remove heat from the semiconductor wafer via the handler wafer.

6. The semiconductor testing device of claim 5, wherein the handler wafer is one of: a silicon handler wafer, or a thermally conductive handler wafer.

7. The semiconductor testing device of claim 6, wherein the handler wafer includes integrated cooling channels configured to spread and remove heat from the semiconductor wafer.

8. The semiconductor testing device of claim 6, wherein the handler wafer includes through-silicon via (TSV) configured to spread and remove heat from the semiconductor wafer.

9. The semiconductor testing device of claim 1, wherein the semiconductor testing device is configured to test the devices within a temperature range from −55° C. to 150° C.

10. The semiconductor testing device of claim 1, wherein the semiconductor testing device is configured to power up at least one of the devices via the probe heads.

11. A method of fabricating a semiconductor testing device, the method comprising:
forming N devices under test coupled to each other, wherein N is an integer;
forming N−1 probe heads, wherein:
an M-th probe head is formed by electrically connecting a device 1 to a device N-M of the N devices under test to each other; and
M is an integer between 1 and N−1, and
testing an M-th device of the N devices under test by the M-th probe head.

12. The method of claim 11, further comprising:
upon testing the M-th device under test by the M-th probe head, forming an M+1 probe head by electrically connecting the device 1 to a device N-M+1 of the N devices under test; and
testing an M+1-th device of the N devices under test by the M+1 probe head.

13. The method of claim 12, wherein:
at least one of the N devices under test is a semiconductor wafer; and
the semiconductor wafer is one of: a functional wafer, a full thickness wafer, or a thinned wafer.

14. The method of claim 13, further comprising:
connecting the semiconductor wafer to a handler wafer; and
spreading and removing heat from the semiconductor wafer by the semiconductor testing device via the handler wafer.

15. The method of claim 13, further comprising:
forming integrated cooling channels within a handler wafer; and
spreading and removing heat from the semiconductor wafer via the integrated cooling channels.

16. The method of claim 13, further comprising:
forming through-silicon via (TSV); and
spreading and removing heat from the semiconductor wafer via the TSV.

17. The method of claim 11, further comprising powering up at least one of the N devices under test by the probe heads.

18. A semiconductor testing device, comprising:
a test head comprising;
one or more electrical connections; and
one or more testing probes;
a device under test; and
a handler wafer connected to the device under test, wherein the semiconductor testing device is configured to power up the device under test during testing.

19. The semiconductor testing device of claim 18, wherein the test head further comprises heating and cooling channels, and wherein the test head is configured to heat up and cool down the test head from −55° C. to 150° C.

20. The semiconductor testing device of claim 18, wherein the device under test is one of: a functional wafer, a full thickness wafer, or a thinned wafer.
